(19) United States
(12) Patent Application Publication
(10) Pub. No.: US 2018/0342698 A1
(43) Pub. Date: Nov. 29, 2018

(54) OLED DEVICE PACKAGING COMPONENT, PACKAGING METHOD AND DISPLAY DEVICE THEREOF

(71) Applicant: SHENZHEN CHINA STAR OPTOELECTRONICS TECHNOLOGY CO., LTD., Shenzhen, Guangdong (CN)

(72) Inventor: Wenjie LI, Shenzhen, Guangdong (CN)

(73) Assignee: Shenzhen China Star Optoelectronics Technology Co., Ltd., Shenzhen, Guangdong (CN)

(21) Appl. No.: 15/541,550

(22) PCT Filed: Jun. 23, 2017
(86) PCT No.: PCT/CN2017/089705

§ 371 Date: Jul. 5, 2017

(30) Foreign Application Priority Data
May 26, 2017 (CN) 201710384079.6

(51) Int. Cl. H01L 51/52; H01L 51/00; H01L 51/56; H01L 27/32

(52) U.S. Cl. CPC H01L 51/5253; H01L 51/0005; H01L 51/529; H01L 2251/558; H01L 27/3241; H01L 2251/5338; H01L 51/56

(57) ABSTRACT

The present invention discloses an OLED device packaging component, a packaging method and a display device thereof. Disposing a thermal conductive layer in a package film of the packaged OLED device, and disposing a first pattern area and a second pattern area staggered in a predetermined direction on a side of the thermal conductive layer away from the OLED device. A thickness of the thermal conductive layer in the first pattern area is less than the thickness in the second pattern area.

### FIELD OF THE INVENTION

The present disclosure is related to a field of display technology, and in particular it relates to an OLED (Organic Light Emitting Diode) device packaging component, a packaging method and a display device thereof.

### BACKGROUND OF THE INVENTION

OLED as a new generation of display, apart from the traditional liquid crystal displays, it does not need to use backlight. By making an organic thin film on a substrate, the organic thin film is wrapped between a cathode metal and an anode metal and is lighten by applying voltage between the two electrodes. Since an organic material of the organic thin film is very sensitive to water vapor and oxygen, the penetration of water/oxygen will greatly reduce the life of an OLED device. So, in order to achieve the market for its service life and stability requirements, an industry requirement for packaging effect of OLED device is very high.

Currently, the industry generally uses thin film packaging method for packaging an OLED device. As shown in FIG. 1, forming a package film 12 on an OLED device 11 by alternately depositing a barrier layer 121 and a buffer layer 122 for covering the OLED device 11. The barrier layer 121 serves as an effective barrier layer for water/oxygen, and its main component is an inorganic substance, and in the preparation process there will be pinholes, particle and other defects. The main component of the buffer layer 122 is an organic substance, which serves to cover the defects of the barrier layer 121 to achieve planarization. In order to improve material utilization to save costs, the current technology generally forms the buffer layer 122 by ink-jet printing (IJP) method, and how to prevent droplet overflow from forming the buffer layer 122 is very critical. In addition, thin design trend of the OLED device 11 makes its wiring more intensive, and how to improve the fast heat dissipation capability of the OLED device 11 is also very important.

### SUMMARY OF THE INVENTION

In view of this, the present disclosure provides an OLED device packaging component, a packaging method and a display device thereof. It can help improve fast heat dissipation capability of an OLED device, and to prevent droplet overflow from forming a package film by IJP technology.

An embodiment of the OLED device packaging component of the present disclosure comprises:

A substrate for carrying the OLED device.

A first barrier layer covering the OLED device.

A thermal conductive layer formed on the first barrier layer, a side of the thermal conductive layer away from the OLED device is disposed with a first pattern area and a second pattern area, a thickness of the thermal conductive layer in the first pattern area is less than the thickness in the second pattern area.

A buffer layer formed in the first pattern area of the thermal conductive layer.

A second barrier layer covering the buffer layer and the thermal conductive layer.

An embodiment of the display device of the present disclosure comprises the OLED device packaging component, wherein the OLED device packaging component comprises:

The substrate for carrying the OLED device.

The first barrier layer covering the OLED device.

The thermal conductive layer formed on the first barrier layer, a side of the thermal conductive layer away from the OLED device is disposed with the first pattern area and the second pattern area, the thickness of the thermal conductive layer in the first pattern area is less than the thickness in the second pattern area

The buffer layer formed in the first pattern area of the thermal conductive layer.

The second barrier layer covering the buffer layer and the thermal conductive layer.

An embodiment of the OLED device packaging method of the present disclosure comprises:

Providing the substrate.

Carrying the OLED device on the substrate;

Covering the first barrier layer of the OLED device;

Forming the thermal conductive layer on the first barrier layer, a side of the thermal conductive layer away from the OLED device is disposed with the first pattern area and the second pattern area, the thickness of the thermal conductive layer in the first pattern area is less than the thickness in the second pattern area.

Forming the buffer layer in the first pattern area of the thermal conductive layer.

Covering the buffer layer and the thermal conductive layer with the second barrier layer.

The beneficial effect is: the present disclosure is designed to dispose the thermal conductive layer between the first barrier layer and the second barrier layer. That is, a thermal conductive layer is disposed in the package film of the OLED device, to improve the rapid heat dissipation capacity of the OLED device, and a side of the thermal conductive layer away from the OLED device is patterned, the thickness of the thermal conductive layer in the first pattern area is less than the thickness in the second pattern area, the droplet overflow can be prevented by the first pattern area accommodating the droplet from forming the buffer layer by IJP technology.

### BRIEF DESCRIPTION OF THE DRAWINGS

FIG. 1 is a schematic cross-sectional diagram of an OLED device packaging component in the current technology.

FIG. 2 is a schematic cross-sectional diagram showing an embodiment of a display device in the present disclosure.

FIG. 3 is a structure top-view diagram showing a first embodiment of the buffer layer and the thermal conductive layer in FIG. 2.

FIG. 4 is a structure top-view diagram showing a second embodiment of the buffer layer and the thermal conductive layer in FIG. 2.

FIG. 5 is a structure top-view diagram showing a third embodiment of the buffer layer and the thermal conductive layer in FIG. 2.

FIG. 6 is a structure top-view diagram showing a fourth embodiment of the buffer layer and the thermal conductive layer in FIG. 2.

FIG. 7 is a schematic diagram of manufacturing the buffer layer and the thermal conductive layer shown in FIG. 2.

FIG. 8 is a structure top-view diagram of manufacturing a mask plate of the thermal conductive layer shown in FIG. 5.

FIG. 9 is a schematic flow diagram showing an embodiment of an OLED device packing method in the present disclosure.

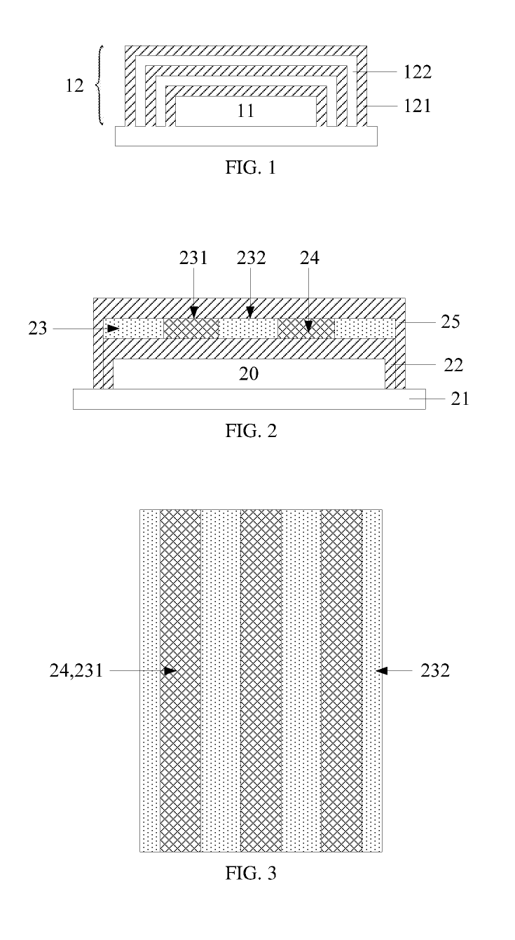

### DETAILED DESCRIPTION OF PREFERRED EMBODIMENTS

The present disclosure in conjunction with the following diagrams in the embodiments, the technical solutions of the various exemplary embodiments of the present disclosure provides clearly and completely described. In the case of no conflict, each of the following examples and the features in the embodiments may be combined with each other.

Referring to FIG. 2, which is an embodiment of a display device in the present disclosure. The display device comprises an OLED device 20 and a packaging component of the OLED device 20. The packaging component can comprise a substrate 21, a first barrier layer 22, a thermal conductive layer 23 and a buffer layer 24.

The OLED device 20 is disposed on the substrate 21, the OLED device 20 can be a bottom light emitting device, that is, the substrate 21 is disposed in the light emitting direction of the OLED device 20. The substrate 21 can be a transparent glass substrate or a transparent plastic substrate, for example, when manufacturing a flexible display device, the substrate 21 can be a flexible, transparent PI (Polyimide) substrate.

The first barrier layer 22 is a structure covering the OLED device. In particular, the first barrier layer 22 can cover the upper surface of the OLED device 20 and the respective side surfaces, and a side of the first barrier layer 22 away from the OLED device 20 is a smooth plane. The thickness of the first barrier layer 22 can be 100 nm to 2 um, and the manufacturing material of the first barrier layer 22 can be an inorganic substance, such as silicon nitride, silicon oxide, silicon nitride, aluminum nitride, aluminum oxide, or aluminum oxide. In addition, the present disclosure can form the first barrier layer 22 without using a mask plate, for example, using any one of Sputtering method, PECVD (Plasma Enhanced Chemical Vapor Deposition) method, or ALD (Atomic layer deposition) method to form the first barrier layer 22.

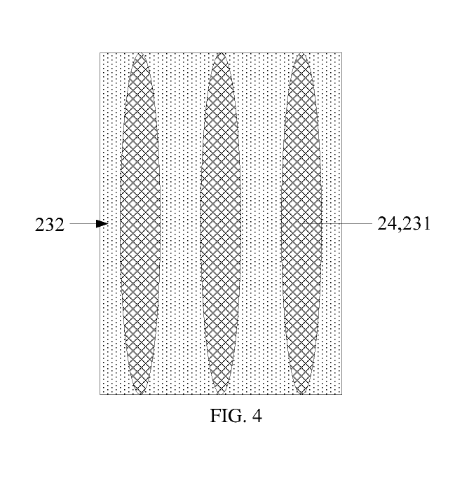

A side of the thermal conductive layer 23 away from the OLED device 20 having a predetermined pattern. Referring to FIG. 2 and FIG. 3, the predetermined pattern can comprise a first pattern area 231 and a second pattern area 232. The thermal conductive layer 23 in the first pattern area 231 can expose the surface of the first barrier layer 22. That is, the first pattern area 231 is a hollow area. The first pattern area 231 comprises a plurality of strip-shaped regions arranged alternately in the direction parallel to the substrate 21 (horizontal direction), each of the strip-shaped regions is a rectangular.

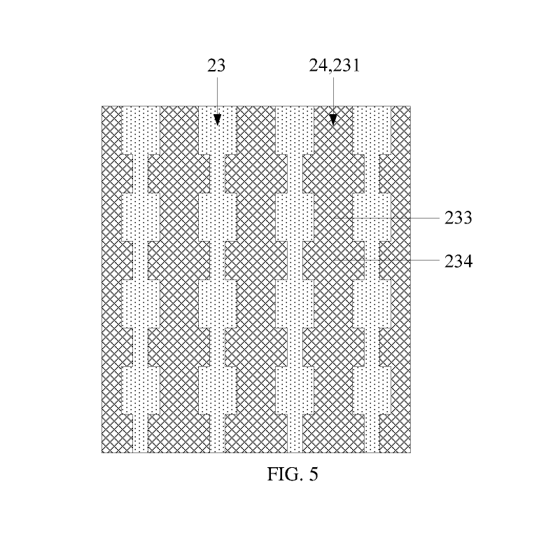

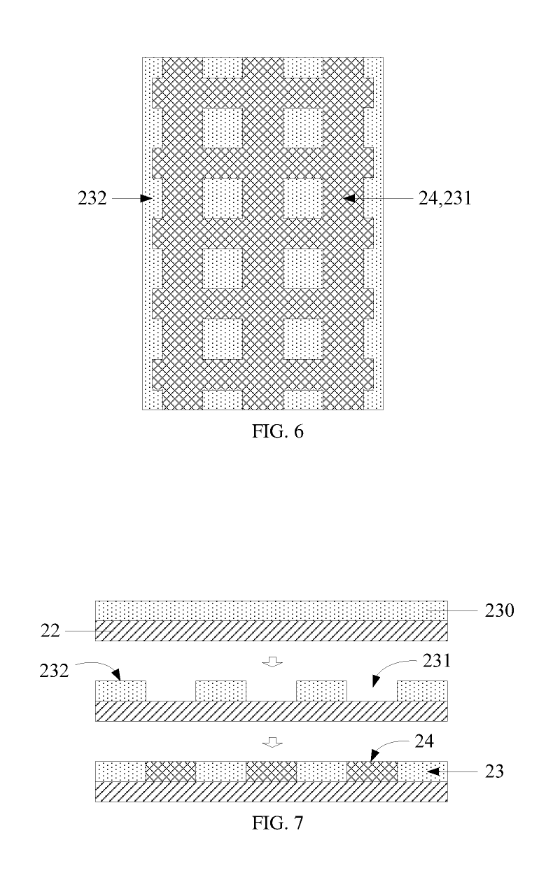

Of course, the strip-shaped regions can also be disposed in other shapes in the present disclosure, for example drop-shaped; in another example, referring to FIG. 4, the strip-shaped regions can be oval; also for example, referring to FIG. 5, the strip-shaped regions can also comprise a first sub-region 233 and a second sub-region 234 connected alternately in a vertical direction, the first sub-region 233 and the second sub-region 234 can be rectangular, and a width of the first sub-region 233 in the horizontal direction is smaller than the width of the second sub-region 234. In addition, referring to FIG. 6, the first pattern area 231 can also be in a mesh structure.

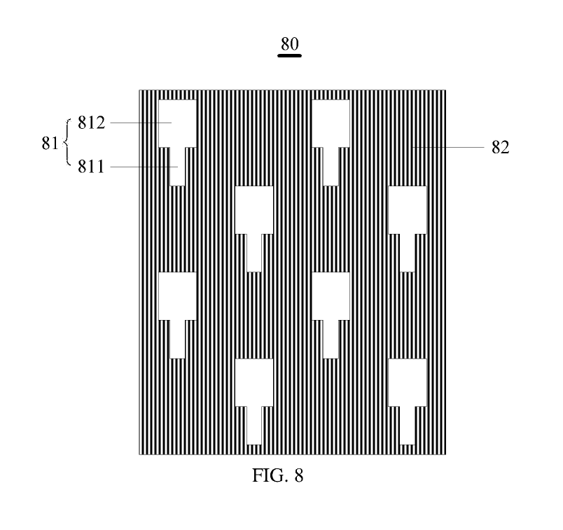

In the present disclosure, the thermal conduction layer 23 can be obtained by patterning an entire surface of the thermal conduction layer using an etching process. As shown in FIG. 7, firstly, covering an entire surface of a thermal conductive layer 230 on the first barrier layer 22 using thermal deposition method. Wherein a material of the thermal conductive layer 230 can be a highly thermal conductive metal, such as silver with a purity greater than or equal to 99.99%, a vacuum chamber is required to have a vacuum of less than 5*10⁻⁵ Pa for thermal deposition method, a temperature required for thermal deposition method can be 1000 to 1500° C., and the deposition rate is 5 to 15 Å/sec, thereby the thermal conductive layer 230 having the thickness of 50 to 500 nm can be obtained. Then, etching the thermal conductive layer 230 to remove portions of the thermal conductive layer 230 in the first pattern area 231.

Of course, the present disclosure can also directly form the thermal conductive layer 23 having the predetermined pattern on the mask plate. In Particular: firstly, placing the mask plate on the first barrier layer 22, forming the thermal conductive layer 23 having the pattern shown in FIG. 5 as an example. The present disclosure can use a mask plate 80 as shown in FIG. 8, the mask plate 80 comprises a hollow area 81 and a non-hollow area 82, the hollow area 81 comprises a first area 811 and a second area 812 which are in conductive with each other, the width of the first area 811 in the horizontal direction is smaller than the width of the second area 812, and the first area 811 and the second area 812 can be rectangle. Then, depositing a thermal conductive material on the first barrier layer 22 through the hollow area 81 of the mask plate 80 by thermal deposition method, to form a thermal conductive layer 23 having the pattern as shown in FIG. 5.

When a number of the hollow area 81 of the mask plate 80 is smaller than the number of the first pattern area 231 of the thermal conductive layer 23, the present disclosure can move the mask plate 80 horizontally to a predetermined area after the primary thermal deposition process, and perform the thermal deposition process again. The distance and the number of times of movement are determined based on the pattern and the number of the first pattern area 231 and the second pattern area 232 designed by the first barrier layer 22, thereby forming the thermal conductive layer 23 having the predetermined pattern.

Of course, the present disclosure can also use ALD method or Sputtering method, and in combination with the mask plate 80 to form the thermal conductive layer 23 having the predetermined pattern.

Further, a manufacturing material of the thermal conductive layer 23 can also be copper, gold, aluminum, and alloys thereof.

Continually referring to FIG. 2˜FIG. 7, the buffer layer 24 can be formed only on the first pattern area 231 of the thermal conductive layer 23, where the thickness of the buffer layer 24 is the same as the thickness of the thermal conductive layer 23. Of course, the buffer layer 24 can also cover the first pattern area 231 and the second pattern area 232 of the thermal conductive layer 23. That is, the buffer layer 24 is an entire surface structure for completely covering the thermally conductive layer 23.

A manufacturing material of the buffer layer 24 can be an organic material, such as epoxy resin, silicon-based polymer, and PMMA (polymethylmethacrylate). Forming the buffer layer 24 without the mask plate in the present disclosure, thereby saving the design and production costs of the mask plate, and reducing the production and manufacturing costs of the entire package assembly. For example, an epoxy resin solution having a viscosity of 5 to 100 cPs (centipoise), in the present disclosure, the epoxy resin solution can be dripped in the first pattern area 231 of the thermal conductive layer 23 by any one of IJP method, ODF (One Drop Filling) method, or Nozzle printing method, and then placed in an environment of 80 to 100° C. for 60 to 90 minutes, thereby curing to form the buffer layer 24. Of course, the present disclosure can also cure the epoxy resin solution by UV (Ultraviolet) curing to form the buffer layer 24.

In the present disclosure, the first barrier layer 22 is an effective barrier layer of water/oxygen. The buffer layer 24 for covering the first barrier layer 22 to achieve planarization. The thermally conductive layer 23 for heat conduction and heat dissipation. The thermal conductive layer 23, the buffer layer 24 and the first barrier layer 22 can be considered as the packaging films of the OLED device 20. Compared with the current technology, the thermal conductive layer 23 of the present disclosure contributes to improve the rapid heat dissipation capacity of the OLED device 20, and the first pattern area 231 can accommodate droplets when the buffer layer 24 is formed by IJP method or the like, to prevent droplet overflow.

Continually referring to FIG. 2, the packaging component of an embodiment of the present disclosure can further comprise a second barrier layer 25 covering the buffer layer and the thermal conductive layer. A manufacturing material of the second barrier layer 25 can be the same with the manufacturing material of the first barrier layer 22. In the present disclosure, the second barrier layer 25 can be formed without the mask plate. For example, the second barrier layer 25 is formed by any one of ODF method, IJP method, or Nozzle printing method to save costs.

A side of the second barrier layer 25 away from the buffer layer 24 can be a smooth plane. When the protective film or the touch film having the touch sensor function is attached to a side of the second barrier layer 25 away from the buffer layer 24, the present disclosure does not appear in the vicinity of the smooth surface with the protective film or the touch film, so that the bubble can be avoided when the OLED device 20 is displayed.

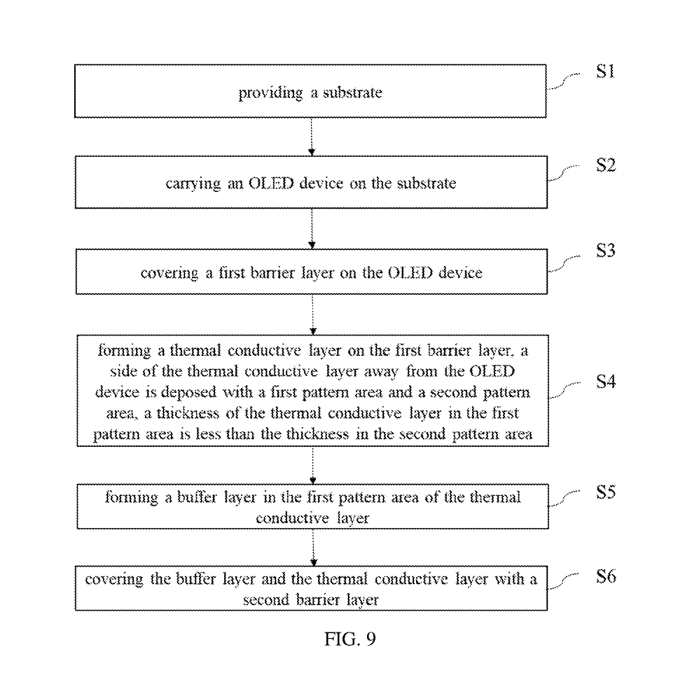

Referring to FIG. 9, which is an embodiment of an OLED device packaging method in the present disclosure. The packaging method can comprise the following steps S91˜S95.

S91: providing a substrate.

The substrate comprises but not limited to a transparent glass substrate or a transparent plastic substrate. For example, when manufacturing a flexible display device, the substrate can be a bendable transparent PI substrate.

S92: carrying an OLED device on the substrate.

The OLED device is disposed on the substrate, and the OLED device can be a bottom light emitting device, the substrate is disposed in the light emitting direction of the OLED device.

S93: covering a first barrier layer on the OLED device.

The first barrier layer is a structure covering on the OLED device, particularly, the first barrier layer can cover the upper surface of the OLED device and the respective side surfaces, and a side of the first barrier layer away from the OLED device is a smooth plane. The thickness of the first barrier layer can be 100 nm˜2 um, the manufacturing material can be an inorganic substance, such as silicon nitride, silicon oxide, silicon nitride, aluminum nitride, aluminum oxide, and nitrogen oxides of aluminum. Furthermore, in the present disclosure, the first barrier layer can be formed without the mask plate, for example, using any one of Sputtering method, PECVD method, or ALD method to form the first barrier layer.

S94: forming a thermal conductive layer on the first barrier layer, a side of the thermal conductive layer away from the OLED device is deposed with a first pattern area and a second pattern area, a thickness of the thermal conductive layer in the first pattern area is less than the thickness in the second pattern area.

A side of the thermal conductive layer away from the OLED device having the predetermined pattern. The predetermined pattern can comprise the first pattern area and the second pattern area. The thermal conductive layer in the first pattern area can expose the surface of the first barrier layer, that is, the first pattern area is a hollow area. The first pattern area comprises a plurality of strip-shaped regions arranged alternately in the direction parallel to the substrate, each of the strip-shaped regions is a rectangle.

Of course, the strip-shaped regions can also be disposed in other shapes in the present disclosure, such as drop-shaped or oval; also for example, the strip-shaped regions can also comprise the first sub-region and the second sub-region connected alternately in a vertical direction, the first sub-region and the second sub-region can be rectangular, and the width of the first sub-region in the horizontal direction is smaller than the width of the second sub-region. In addition, the first pattern area can also be in a mesh structure.

In the present disclosure, the thermal conduction layer can be obtained by patterning an entire surface of the thermal conduction layer using etching process. In particular, firstly, covering an entire surface of the thermal conductive layer on the first barrier layer by thermal deposition method. Wherein the material of the thermal conductive layer can be a highly thermal conductive metal, such as silver with a purity greater than or equal to 99.99%, the vacuum chamber is required to have a vacuum of less than 5*10⁻⁵ Pa for thermal deposition method, the temperature required for thermal deposition method can be 1000 to 1500° C., and the deposition rate is 5 to 15 Å/sec, thereby the thermal conductive layer having the thickness of 50 to 500 nm can be obtained. Then, etching the thermal conductive layer to remove portions of the thermal conductive layer in the first pattern area.

Of course, the present disclosure can also directly form the thermal conductive layer having the predetermined pattern on the mask plate. In particular, firstly, placing the mask plate on the first barrier layer, forming the thermal conductive layer having the pattern shown in FIG. 5 as an example. The mask plate comprises a hollow area and a non-hollow area. The hollow area comprises the first area and the second area which are in conductive with each other, and the width of the first area in the horizontal direction is smaller than the width of the second area. The first area and the second area can be rectangle. Then, depositing the thermal conductive material on the first barrier layer through the hollow area of the mask plate by thermal deposition method, to form the thermal conductive layer.

When the number of the hollow area of the mask plate is smaller than the number of the first pattern area of the thermal conductive layer, the present disclosure can move the mask plate horizontally to a predetermined area after the primary thermal deposition process, and perform the thermal deposition process again. The distance and the number of times of movement are determined based on the pattern and the number of the first pattern area and the second pattern area designed by the first barrier layer, thereby forming the thermal conductive layer having the predetermined pattern.

Of course, the present disclosure can also use ALD method or Sputtering method, and in combination with the mask plate to form the thermal conductive layer having the predetermined pattern.

Further, the manufacturing material of the thermal conductive layer can also be copper, gold, aluminum, and alloys thereof.

S95 forming a buffer layer in the first pattern area of the thermal conductive layer.

The manufacturing material of the buffer layer can be an organic material, such as epoxy resin, silicon-based polymer, and PMMA. Forming the buffer layer without the mask plate in the present disclosure, thereby saving the design and production costs of the mask plate, and reducing the production and manufacturing costs of the entire package assembly. For example, the epoxy resin solution having a viscosity of 5 to 100 cPs (centipoise), in the present disclosure, the epoxy resin solution can be dripped in the first pattern area of the thermal conductive layer by any one of IJP method, ODF method, or Nozzle printing method, and then placed in an environment of 80 to 100° C. for 60 to 90 minutes, thereby curing to form the buffer layer. Of course, the present disclosure can also cure the epoxy resin solution by UV curing to form the buffer layer.

S96: covering the buffer layer and the thermal conductive layer with a second barrier layer.

The manufacturing material of the second barrier layer can be the same with the manufacturing material of the first barrier layer. In the present disclosure, the second barrier layer can be formed without the mask plate, for example, the second barrier layer 25 is formed by any one of ODF method, IJP method, or Nozzle printing method to save costs.

A side of the second barrier layer away from the buffer layer can be a smooth plane. When the protective film or the touch film having the touch sensor function is attached to a side of the second barrier layer away from the buffer layer, the present disclosure does not appear in the vicinity of the smooth surface with the protective film or the touch film, so that the bubble can be avoided when the OLED device is displayed.

The packaging method of the OLED device described above can be used to produce the package component with the structure shown in FIG. 2, thus having the same beneficial effect.

The embodiments described above are only embodiments of the present disclosure, not intended to limit the scope of the present disclosure, all utilize the present specification and drawings taken equivalent structures or equivalent process, or other direct or indirect application related technical fields shall fall within the scope of protection of the present disclosure.

What is claimed is:

1. An OLED device packaging component, wherein the packing component comprises:
a substrate for carrying the OLED device;
a first barrier layer covering the OLED device;
a thermal conductive layer formed on the first barrier layer, a side of the thermal conductive layer away from the OLED device is disposed with a first pattern area and a second pattern area, a thickness of the thermal conductive layer in the first pattern area is less than the thickness in the second pattern area
a buffer layer formed in the first pattern area of the thermal conductive layer; and
a second barrier layer covering the buffer layer and the thermal conductive layer.

2. The OLED device packaging component according to claim 1, wherein the thermal conductive layer exposes a surface of the first barrier layer in the first pattern area.

3. The OLED device packaging component according to claim 2, wherein the first pattern area comprises a plurality of strip-shaped regions arranged alternately, or the first pattern area is a mesh structure.

4. The OLED device packaging component according to claim 2, wherein the strip-shaped region comprises at least one of a rectangular, an oval, and a drop-shaped.

5. A display device, wherein the display device comprises an OLED device packaging component, the OLED device packaging component comprises:
a substrate for carrying the OLED device;
a first barrier layer covering the OLED device;
a thermal conductive layer formed on the first barrier layer, a side of the thermal conductive layer away from the OLED device is disposed with a first pattern area and a second pattern area, a thickness of the thermal conductive layer in the first pattern area is less than the thickness in the second pattern area;
a buffer layer formed in the first pattern area of the thermal conductive layer; and
a second barrier layer covering the buffer layer and the thermal conductive layer.

6. The display device according to claim 5, wherein the thermal conductive layer exposes a surface of the first barrier layer in the first pattern area.

7. The display device according to claim 6, wherein the first pattern area comprises a plurality of strip-shaped regions arranged alternately, or the first pattern area is a mesh structure.

8. The display device according to claim 6, wherein the strip-shaped region comprises at least one of a rectangular, an oval, and a drop-shaped.

9. An OLED device packaging method, wherein the packaging method comprises:
providing a substrate;
carrying the OLED device on the substrate;
covering a first barrier layer on the OLED device;
forming a thermal conductive layer on the first barrier layer, a side of the thermal conductive layer away from the OLED device is disposed with a first pattern area and a second pattern area, a thickness of the thermal conductive layer in the first pattern area is less than the thickness in the second pattern area;
forming a buffer layer in the first pattern area of the thermal conductive layer; and
covering the buffer layer and the thermal conductive layer with a second barrier layer.

10. The OLED device packaging method according to claim 9, wherein the thermal conductive layer exposes a surface of the first barrier layer in the first pattern area.

11. The OLED device packaging method according to claim 10, wherein
forming the thermal conductive layer on the first barrier layer comprises:
covering an entire surface of the thermal conductive layer on the first barrier layer; and
etching the thermal conductive layer to remove portions of thermal conductive layer in the first pattern area; and
forming the buffer layer in the first pattern area of the thermal conductive layer comprises:
filling an organic solution in the first pattern area of the thermal conductive layer by ink jet printing technology; and
curing the organic solution to form the buffer layer.

12. The OLED device packaging method according to claim 10, wherein
forming the thermal conductive layer on the first barrier layer comprises:
disposing a mask plate having a hollow area and a non-hollow area on the first barrier layer; and
depositing a thermal conductive material on the first barrier layer through the hollow area of the mask plate; and
forming the buffer layer in the first pattern area of the thermal conductive layer comprises:
filling an organic solution in the first pattern area of the thermal conductive layer by ink jet printing technology; and
curing the organic solution to form the buffer layer.

13. The OLED device packaging method according to claim 9, wherein the first pattern area comprises a plurality of strip-shaped regions arranged alternately, or the first pattern area is a mesh structure.

14. The OLED device packaging method according to claim 9, wherein the strip-shaped region comprises at least one of a rectangular, an oval, and a drop-shaped.
